(19) United States
(12) Patent Application Publication
(10) Pub. No.: US 2025/0087597 A1
(43) Pub. Date: Mar. 13, 2025

(54) APPARATUS FOR SHIELDING ELECTROMAGNETIC WAVE OF SEMICONDUCTOR PACKAGE

(71) Applicant: JOINSET CO., LTD., Ansan-si (KR)

(72) Inventors: Sun-Ki Kim, Gunpo-si (KR); Tae-Man Kang, Ansan-si (KR); Jin-San Kim, Ansan-si (KR)

(21) Appl. No.: 18/827,634

(22) Filed: Sep. 6, 2024

(30) Foreign Application Priority Data
Sep. 8, 2023 (KR) 10-2023-0119804
Aug. 21, 2024 (KR) 10-2024-0112377

(51) Int. Cl. H01L 23/552; H01L 23/00

(52) U.S. Cl. CPC H01L 23/552; H01L 24/16; H01L 24/29; H01L 2224/16225; H01L 2224/2919; H01L 2924/3025

(57) ABSTRACT

Provided is an apparatus for shielding an electromagnetic wave that efficiently shields the electromagnetic wave generated from a semiconductor chip mounted on a circuit board, while releasing heat generated from the semiconductor chip. The apparatus may surround and be fixed to along a side surface of the semiconductor chip to provide an electrically closed circuit with respect to the semiconductor chip, thereby efficiently shielding the electromagnetic wave generated from the semiconductor chip.

### REFERENCE TO RELATED APPLICATIONS

This application claims the priority benefit of Korean Patent Application No. 10-2023-0119804 filed on Sep. 8, 2023 and Korean Patent Application No. 10-2024-0112377 filed on Aug. 21, 2024, the entire contents of which are incorporated herein by reference.

### FIELD OF THE INVENTION

The present disclosure relates to an apparatus for shielding an electromagnetic wave of a semiconductor package, and more particularly, to an apparatus which is capable of efficiently shielding an electromagnetic wave generated from a side surface of a semiconductor chip mounted on a circuit board, while releasing heat generated from the side surface of the semiconductor chip to the outside.

### BACKGROUND OF THE INVENTION

As electronic devices and information communication equipment become smaller and more integrated, the electronic devices and information communication equipment are increasingly affected by heat, static electricity, and electromagnetic waves.

According to conventional technologies, a typical metal shield can and a thermal conductive member may be used for electromagnetic wave shielding, heat transfer, and heat dispersion of electronic components or electronic component modules such as semiconductor chips mounted on a printed circuit board. For example, there are domestic patent registrations Nos. 2048809 and 2318858 by the present applicant.

In other conventional technologies, there are conformal shields, which are provided by depositing, plating, or spraying electrically conductive materials onto epoxy resin molding materials constituting the exterior of semiconductor chips, and compartment shields, which are provided by embedding metal wires or metal chips within the semiconductor chip.

Another conventional technology involves semiconductor chip packaging, in which a semiconductor die, on which the CPU for a computer is mounted on a semiconductor packaging substrate, is covered with a metal shield can, and thermal grease is disposed between the semiconductor die and the metal shield can. The metal shield can serves to mechanically protect the semiconductor die and shield electromagnetic waves generated by the semiconductor die. The metal shield can, together with the thermal grease, receives heat generated by the semiconductor die to disperse and release the heat to the outside.

As such, the metal shield can, which serves as a component that shields the semiconductor chip from electromagnetic waves. The metal shield can has to have a certain minimum size because it has a box-shaped metal body to be mounted on a circuit board by soldering. Thus, when the metal shield can is installed on a circuit board having a relatively small space, such as those found in smartphones, as additional space is required, which presents limitations for its application.

Particularly, since conventional metal shield cans are mounted in such a way that they surround and cover the semiconductor chip equipped on the circuit board in a state in which the metal shield cans and the semiconductor chip are spaced apart from each other and have a relatively large gap therebetween. As a result, the metal shield can is disposed to be apart from the semiconductor chip, which generates electromagnetic waves and heat. Accordingly, there are limitations in economically and efficiently shielding the electromagnetic waves generated by the semiconductor chip or in economically and efficiently transferring and dispersing the heat.

Also, after the metal shield can is mounted on the circuit board, it is difficult to elastically connect the metal shield can to the a planar cooling unit, such as a heat sink, provided on the metal shield can. As a result, the grounding pattern of the circuit board may not be easily electrically connected to the cooling unit, making it necessary to apply a separate EMI gasket to electrically connect the metal shield can and the cooling unit.

In another conventional technology, as described in domestic patent registration No. 2459794, there is provided a method for additionally forming a metal thin film on a semiconductor chip. The heated metal thin film sheet is pressed onto the substrate using an autoclave process in a sealed process chamber, thereby attaching the metal thin film to the surface of the semiconductor chip.

According to the above patent documents, the manufacturing cost increases due to the processes involved in manufacturing and attaching the metal thin film.

Additionally, when multiple semiconductor chips are closely mounted on a single circuit board, there is a limitation in extending the length of the metal thin film, making it difficult to efficiently attach the metal thin film between the sidewalls of adjacent semiconductor chips.

Furthermore, since the thin metal thin film sheet is disposed on the top surface of the semiconductor chip, it does not provide sufficient heat transfer and heat dispersion to the opposing circuit board or metal cover, and it is also inconvenient when reworking (Re-work) the semiconductor chips mounted on the circuit board.

### SUMMARY OF THE INVENTION

The present disclosure provides an apparatus for shielding an electromagnetic wave of a semiconductor package, which may efficiently shield an electromagnetic wave and heat, which are generated from a side surface of a semiconductor chip mounted on a circuit board, at a close distance, while transferring and dispersing the heat.

The present disclosure also provides an apparatus for shielding an electromagnetic wave of a semiconductor package, which may be easily mounted on a circuit board with limited space.

The present disclosure also provides an apparatus for shielding an electromagnetic that may be easily electrically and thermally connected to a metal cover, which covers the semiconductor chip mounted on the circuit board from above, and that may easily protect the semiconductor chip from forces applied by the metal cover or from the outside.

In accordance with an exemplary embodiment of the present invention, an apparatus for shielding an electromagnetic wave of a semiconductor package provided with a semiconductor chip mounted on a circuit board, the apparatus including: a ring-shaped electrically conductive body, wherein the body has heat resistance corresponding to a soldering temperature and includes an accommodation part inside thereof, and the semiconductor chip is accommodated in the accommodation part to allow the body to surround side surfaces of the semiconductor chip, thereby providing an electrically closed circuit, thereby shielding the electromagnetic wave, which leaking out from or is introduced into the side surfaces of the semiconductor chip, wherein at least a portion of inner surfaces of the body is in contact with at least a portion of the side surfaces of the semiconductor chip.

The inner surfaces of the body may be in elastic contact with each of the side surfaces of the semiconductor chip.

The body may include: a contact part that is in contact with and fixed along the side surfaces of the semiconductor chip; and a shielding part that adheres to an outer surface of the contact part so as to be stacked. The contact part and the shielding part may have electrical resistance different from each other.

The body may have a height that is the same as or higher than that of the semiconductor chip.

The body may have a bottom surface that is in electric contact with a grounding pattern provided on the circuit board.

The at least a portion of the inner surfaces of the body may be in direct contact with, or adhere to the at least one of the side surfaces of the semiconductor chip, using an adhesive therebetween, and the body and the adhesive may have thermal conductivity

The body may include: a vertical part; and a horizontal part which extends inward from an upper end of the vertical part, wherein the vertical part and the horizontal part may be integrated with each other.

The apparatus may further include a heat release part that is horizontally integrally expanded outward from the body.

The at least a portion of the inner surfaces of the body may be spaced at a predetermined distance from the semiconductor chip, and the bottom surface of the body may adhere to the circuit board using an adhesive unit.

One or more semiconductor chips may be accommodated in the accommodation part, and the at least a portion of the inner surfaces of the body may be in direct contact with or adhere to the at least one of the side surfaces of the semiconductor chip, using an adhesive therebetween.

The accommodation part, when the semiconductor chip is viewed from top to bottom in a vertical direction, may allow the entire top surface of the semiconductor chip to be exposed to the outside.

### BRIEF DESCRIPTION OF THE DRAWINGS

Exemplary embodiments can be understood in more detail from the following description taken in conjunction with the accompanying drawings, in which:

FIG. 1 is an exploded view of an apparatus for shielding an electromagnetic wave according to an exemplary embodiment of the present invention;

FIG. 2 is a view illustrating a state in which the apparatus for shielding the electromagnetic wave is coupled to a semiconductor chip;

FIG. 3 is a view of an apparatus for shielding an electromagnetic wave according to another embodiment of the present invention;

FIG. 4 is a view illustrating a structure in which the apparatus for shielding the electromagnetic wave is fixed to the semiconductor chip;

FIG. 5 is a view illustrating a modified example of the apparatus for shielding the electromagnetic wave;

FIG. 6 is a view of an apparatus for shielding an electromagnetic wave according to further another embodiment of the present invention; and

FIG. 7 is a view of an apparatus for shielding an electromagnetic wave according to further another embodiment of the present invention.

### DETAILED DESCRIPTION OF THE INVENTION

The technical terms used in the present invention are employed merely to describe specific embodiments and are not intended to limit the invention. Unless otherwise defined, all terms (including technical and scientific terms) used herein have the same meaning as commonly understood by one of ordinary skill in the art to which this invention belongs. It should be interpreted in the sense generally understood by those skilled in the art and should not be interpreted in an unduly broad or unduly narrow manner.

An apparatus for shielding an electromagnetic wave (hereinafter, referred to as an electromagnetic wave shielding apparatus) according to the present invention may be applied not only to semiconductor chips mounted on circuit boards but also to semiconductor packages where the semiconductor chip is electrically connected to a substrate via lead frames, wire bonding, or flip-chip bonding, regardless of whether the structure is sealed with an epoxy resin.

Furthermore, the electromagnetic wave shielding apparatus according to the present invention serves to shield an electromagnetic wave generated and leaking outward from the semiconductor chip, while simultaneously shielding an electromagnetic wave introduced to the semiconductor chip from the outside.

Hereinafter, the present invention will be described in detail with reference to the accompanying drawings. These drawings are provided to aid in the understanding of the invention, and, for convenience of explanation, some components may be depicted with exaggerated dimensions or in a somewhat exaggerated manner.

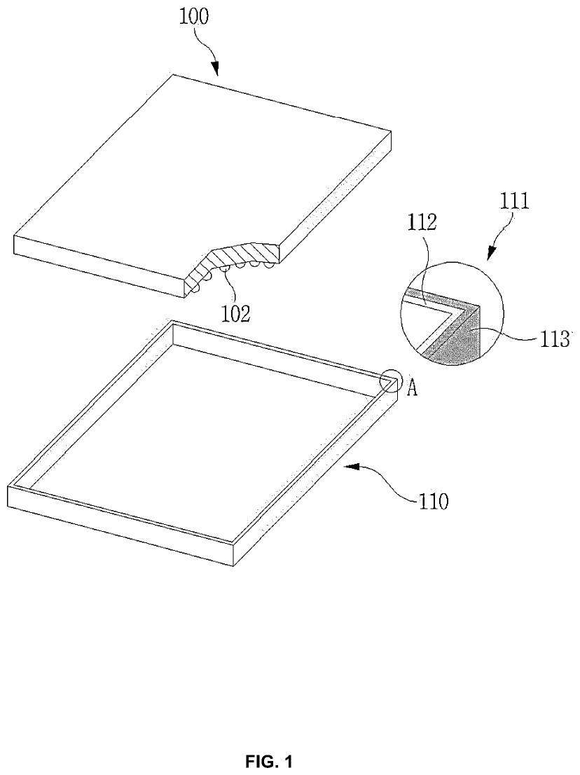

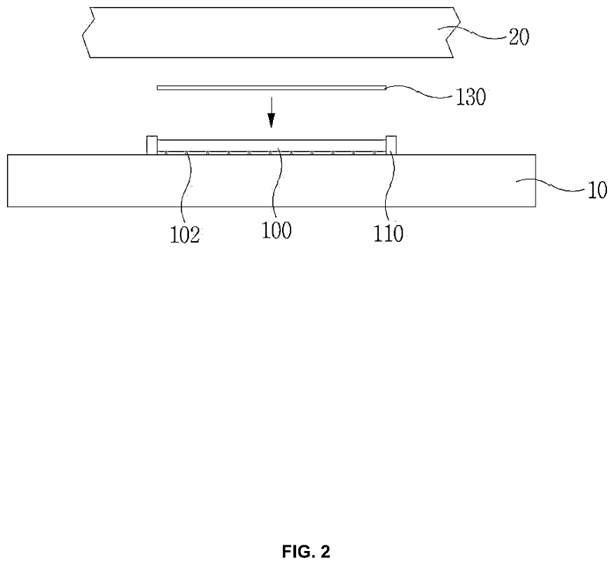

FIG. 1 is an exploded view of the electromagnetic wave shielding apparatus according to an embodiment of the present invention, and FIG. 2 is a view illustrating a state in which the electromagnetic wave shielding apparatus is coupled to a semiconductor chip.

Referring to FIG. 1, an electromagnetic wave shielding apparatus 110 of the present invention is elastically in contact with side surfaces of a semiconductor chip 100 mounted on a circuit board, to create an electrically closed circuit around the semiconductor chip 100, thereby easily shielding the electromagnetic wave generated from each of the side surfaces of the semiconductor chip 100 and easily transferring or dispersing heat generated from the semiconductor chip 100 to the outside.

Structurally, the electromagnetic wave shielding apparatus 110 has a ring-shaped body 111. As shown in an enlarged circle of FIG. 1, the body of the electromagnetic wave shielding apparatus 110 includes a contact part 112 that is in contact with and is fixed along the side surface of the semiconductor chip 100, and a shielding part 113 disposed on an outer surface of the contact part 112, which are stacked together.

The contact part 112 and the shielding portion 113 may have electrical resistance different from each other. For instance, the contact part 112 may be electrically insulated while the shielding part 113 may be electrically conductive, or vice versa. Alternatively, both the contact part 112 and the shielding part 113 may be electrically conductive and have the same electrical resistance.

For example, the electrical resistance of the contact part 112 may be about 1010 ohms or more, and the electrical resistance of the shielding part 113 may be about 1 ohm or less, but those are not limited thereto.

The contact part 112 and the shielding part 113 may also have mechanical properties different from each other. For instance, the contact part 112 may be elastic rubber, while the shielding part 113 may be a non-elastic polymer resin.

The shielding part 113 may be an electrically conductive coating layer provided on the outer surface of the contact part 112, by curing a liquid electrically conductive material corresponding to the shielding part 113.

Also, in order to be easily fitted into the semiconductor chip 100 and to have relatively low electrical resistance, the shielding part 113 may have a hardness higher than that of the contact part 112, while the shielding part 113 has an elongation less than that of the contact part 112.

For example, the hardness of the contact part 112 may be Shore A 30 to 60, and the hardness of the shielding part 113 may be Shore A 45 to 75. The elongation of the contact part 112 may be at least 1.3 times longer than its original length, but it is not limited thereto.

The shape of the ring provided by the body 111 may be circular or rectangular, but it is not limited thereto. For example, when the body 111 has the circular shape, the body 111 may be deformed to be in contact with the side surface of the semiconductor chip 100 having a rectangular shape, and thus a rectangular-ring-shaped shielding apparatus may be provided.

The electromagnetic wave shielding apparatus 110, for example, may be provided in a manner in which liquid electrically conductive rubber is impregnated and then is cured on an outer surface of rolled electrically non-conductive rubber tube to provide an electrically conductive rubber coating layer, and then the tube is cut in a predetermined length, but it is not limited thereto. The electromagnetic wave shielding apparatus 110 may be manufactured by simultaneously extruding or molding liquid non-conductive silicone rubber and liquid conductive silicone rubber.

For example, the body 111 may have a width of about 0.5 mm to about 2 mm.

The body 111 may have a height that is the same as or higher than that of a portion, to which the body 111 is fitted, of the semiconductor chip 100. Thus, as shown in FIG. 2, when a heat-conductive member 130 is disposed between the body 111 and a metal cover 20, the body 111 and the metal cover 20 that is provided from an upper side may be elastically electrically connected to each other.

For example, the body 111 may have a height of about 0.5 mm to about 2 mm.

The semiconductor chip 100, for example, may include BGA 102 protruding from a bottom surface thereof, and be provided by flip-chip bonding and electrically connected to the circuit board 10. The exterior of the semiconductor chip 100 may be sealed with an epoxy resin.

The electromagnetic wave shielding apparatus 110 may be fitted along the side surface of the semiconductor chip 100 either before the semiconductor chip 100 is mounted on the circuit board 10 or after the semiconductor chip 100 is mounted on the circuit board. Thus, the appropriate method may be selected depending on a size or the number of semiconductor chips 100, or the structure of the circuit board on which the semiconductor chip 100 is mounted.

When the electromagnetic wave shielding apparatus 100 is coupled to the semiconductor chip 100, the contact part 112 of the body 111 may be elastically in contact with the semiconductor chip 100 along the side surface of the semiconductor chip 100. Also, the shielding part 113 may shield the electromagnetic wave by providing an electrically closed circuit around the semiconductor chip 100 and transfer or disperse the heat generated from the side surface of the semiconductor chip 100 to the outside.

A bottom surface of the electrically conductive contact part 112 or a bottom surface of the shielding part 113 may be electrically connected to the grounding pattern of the circuit board. For example, on the bottom surface of the body 111, the shielding part 113 may be electrically in contact with the grounding pattern of the circuit board 10, and the contact part 112 may be in contact with an insulated portion of the circuit board 10.

The body 111 of the electromagnetic wave shielding apparatus 110 may have heat resistance corresponding to reflow soldering. When the body 111 is made of elastic rubber, it may be silicone rubber.

Since the body 111 has heat resistance corresponding to the soldering, after the body 111 is fitted into the semiconductor chip 100, the semiconductor chip 100 may be soldered. Additionally, the soldered connections may be reworked after the soldering.

Like this, the body 111 is in contact with and fitted into the side surface of the semiconductor chip 100 may shield the electromagnetic wave generated from the side surface of the semiconductor chip 100 at a close distance and may transfer or disperse the heat generated from the side surface of the semiconductor chip 100 to the outside.

Also, the body 111 may individually shield an electromagnetic wave or may transfer and disperse heat with respect to a plurality of semiconductor chips 100.

Although not shown, the body 111 may be fitted to or disposed on the semiconductor chip 100 so that the body 111 is in contact with a portion of the side surfaces of the semiconductor chip 100, rather than being in contact with and fitted to the entire side surface of the semiconductor chip 100. Shortly, a portion of inner surfaces of the body 111 may be in contact with a portion of the side surfaces of the semiconductor chip 100, or the entire inner surface of the body 111 may be in contact with the entire side surface of the semiconductor chip 100.

In FIG. 2, a top surface of the body 111 of the electromagnetic wave shielding apparatus 110 may be covered by the electrically conductive metal cover 20, and thus a top surface of the shielding part 113 may be electrically elastically connected to the metal cover 20.

According to the structure, since the metal cover 20 is electrically in contact with the semiconductor chip 100 while pressing a top surface of the body 111, the electromagnetic wave generated from the entire semiconductor chip 100 may be shield by the metal cover 20 and the body 111.

Also, when the thermal conductive member 130 is disposed between the metal cover 20 and a top surface of the semiconductor chip 100, the heat generated from the semiconductor chip 100 may be transferred to the metal cover relatively faster through the thermal conductive member 130.

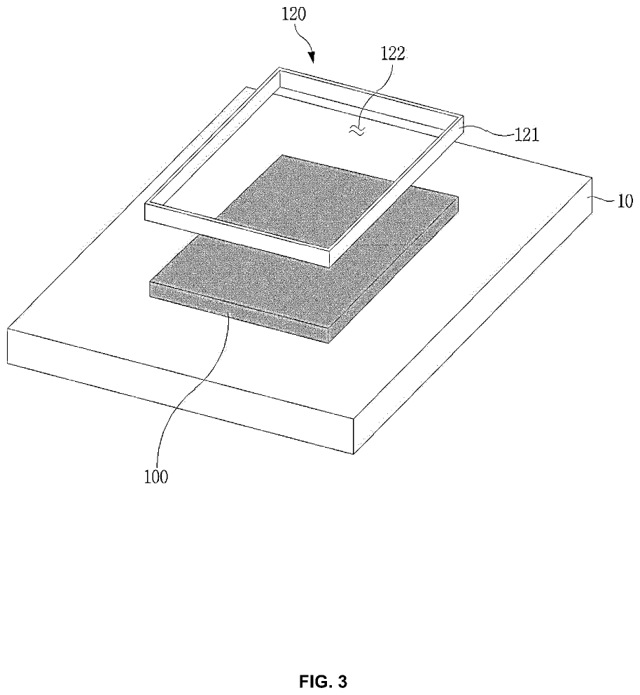

FIG. 3 is a view of an electromagnetic wave shielding apparatus according to another embodiment of the present invention.

An electromagnetic wave shielding apparatus 120 is provided with a ring-shaped electrically conductive body 121 including an accommodation part 122 that may accommodate the semiconductor chip 100. Thus, the electromagnetic wave shielding apparatus 120 may surround the side surface of the semiconductor chip 100 and establish an electrically closed circuit to shield the electromagnetic wave generated from the semiconductor chip 100.

Also, the electromagnetic wave shielding apparatus 120 is directly or indirectly in contact with the side surface of the semiconductor chip 100 to absorb the heat generated from the semiconductor chip 100, thereby transferring and dispersing and thus releasing the heat to the outside.

In FIG. 3, a body 121 of the electromagnetic wave shielding apparatus 120 is provided with a ring-shaped rectangular integrated structure in which the accommodation part 122 is defined in the body 121 to correspond to the semiconductor chip 100 having a rectangular shape.

The accommodation part 122 is defined, such that when viewed from top to bottom in a vertical direction, the entire top surface of the semiconductor chip 100 is exposed to the outside.

The body 121 may have a top surface and a bottom surface, both of which are flat, so that it may be in contact with an opposing circuit board 10 and an electrically conductive cover, which will be described later, over a relatively large area.

The body 121 has appropriate dimensions and shape so that the body 121 may efficiently shield the electromagnetic wave generated from the side surface of the semiconductor chip 100 at a close distance from the side surface of the semiconductor chip, while also effectively transferring and dispersing the heat generated from the semiconductor chip 100 to the outside.

The body 121 may be made of a good electrically conductive metal material, and may be made of a material with good thermal conductivity that is also suitable for soldering with solder cream. For example, when the body 121 is a metal, the body 121 may be manufactured by pressing a copper, iron, or an alloy of these metals, which have a plate-shaped with uniform thickness.

In the present invention, at least one portion of inner surfaces of the body 121 is in contact with and fixed to at least one portion of the side surfaces of the semiconductor chip 100. Here, the description of “fixed to the semiconductor chip”, as described later, broadly implies that the body 121 is directly or indirectly coupled and fixed around the semiconductor chip 100.

At least one portion of the inner surfaces of the body 121 may be reliably in contact with and fixed to at least one portion of the side surfaces of the semiconductor chip 100 with an adhesive 125 therebetween.

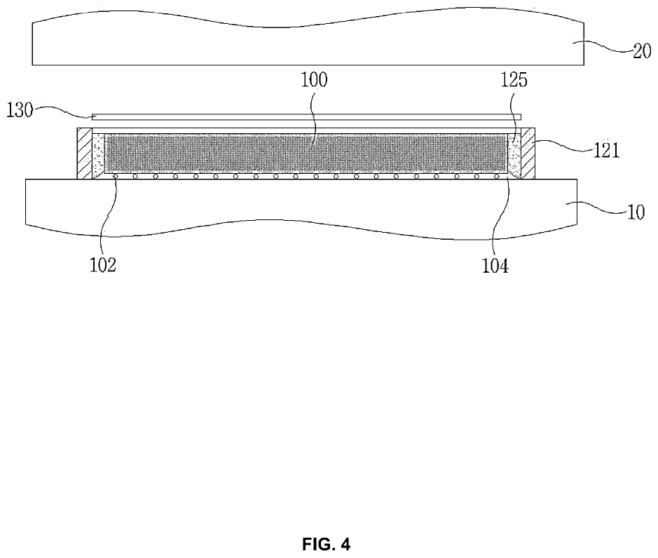

FIG. 4 is a view illustrating a structure in which the electromagnetic wave shielding apparatus is fixed to the semiconductor chip.

In FIG. 4, the body 121 of the electromagnetic wave shielding apparatus 110 may be in contact with the side surface of the semiconductor chip 100 with the adhesive 125 therebetween. Here, each of the inner surfaces of the body 121 may be in contact with and fixed to any one of the four side surfaces of the semiconductor chip 100, or the entire inner surface of the body 121 may be respectively in contact with the side surfaces of the semiconductor chip 100.

When the inner surfaces of the body 121 adhere to and are fixed to four side surfaces of the semiconductor chip 100 by the adhesive 125, heat transfer is symmetrically performed in all directions. When the inner surface of the body 121 adheres to and fixed to one of the four side surfaces of the semiconductor chip 100, the amount of adhesive used is reduced, and the process is simplified, and thus work efficiency may be improved.

For example, when the semiconductor chip 100 has a flip chip bonding structure in which an underfill 104 is applied to a bottom surface of the semiconductor chip 100, the adhesive 125 may adhere to the underfill 104. That is, when the bottom surface of the semiconductor chip 100 adheres to the circuit board 10 by the underfill 104, the adhesive 125 may seep out from the bottom surface of the semiconductor chip 100 to the side surfaces of the semiconductor chip 100 to cover the exposed underfill 104.

The adhesive 125 may be an epoxy resin or silicone rubber with heat resistance suitable for soldering. Here, a liquid adhesive corresponding to the adhesive 125 may be dispensed using such a dispenser, and then be cured.

The adhesive 125 may have electrical insulation properties to prevent electrical connection with respect to the circuit board 10 or to the semiconductor chip, and may have thermal conductivity to provide good heat transfer, but it is not limited thereto.

The adhesive 125 may have a height that is the same as or less than that of the semiconductor chip 100 mounted on the package substrate or the circuit board 10.

The electromagnetic wave shielding apparatus 110 may surround to be fitted and fixed to the side surface of the semiconductor chip 100 either before the semiconductor chip 100 is mounted on the circuit board 10 or after the semiconductor chip 100 is mounted on the circuit board. Thus, the appropriate method may be selected depending on a size or the number of semiconductor chips 100, or the structure of the circuit board on which the semiconductor chip 100 is mounted.

For example, after the semiconductor chip is mounted on the circuit board, the electromagnetic wave shielding apparatus that is suitable for the usage may be applied to surround the side surface of the semiconductor chip and be fixed to the side surface of the semiconductor chip using the adhesive.

In FIG. 4, the bottom surface of the body 121 may be electrically in contact with the grounding pattern provided on the circuit board 10. Here, the electrical contact may be achieved by through soldering with solder, an electrically conductive epoxy or silicone adhesive, or welding.

In this case, since the bottom surface of the body 121 of the electromagnetic wave shielding apparatus 120 is electrically in contact with the grounding pattern of the circuit board 10, the electromagnetic wave shielding effect may be improved.

In another embodiment, when the body 121 is spaced at a predetermined distance from the semiconductor chip 100 to surround the semiconductor chip 100, thereby providing an electrically closed circuit, if the distance is too wide, it may be difficult to fill the adhesive 125 between the body 121 and the semiconductor chip 100. Here, the bottom surface of the body 121 may adhere to and fixed to the circuit board 10 by an adhesive unit such as solder or epoxy adhesive.

The top surface of the body 121 may be pressed and covered by the metal cover 20 and also be electrically connected to the metal cover 20, and the metal cover 20 may cover the top surface of the semiconductor chip 100 as well as the top surface of the body 121.

Here, the metal cover 20 may be a plate-shaped metal sheet or a heat plate, a heat sink, or a vapor chamber.

The body 121 may have a height the same as or higher than that of the semiconductor chip 100 mounted on the circuit board 10. As shown in FIG. 4, when the height of the body 121 is higher than that of the semiconductor chip 100, a gap may be defined between the top surface of the semiconductor chip 100 and the metal cover 20, and a thermal conductive member 130 may be disposed in the gap to allow the heat generated from the semiconductor chip 100 to be quickly transferred in large amounts to the metal cover 20.

The conductive member 130 may be gel, grease, or sheet-shaped thermal conductive rubber.

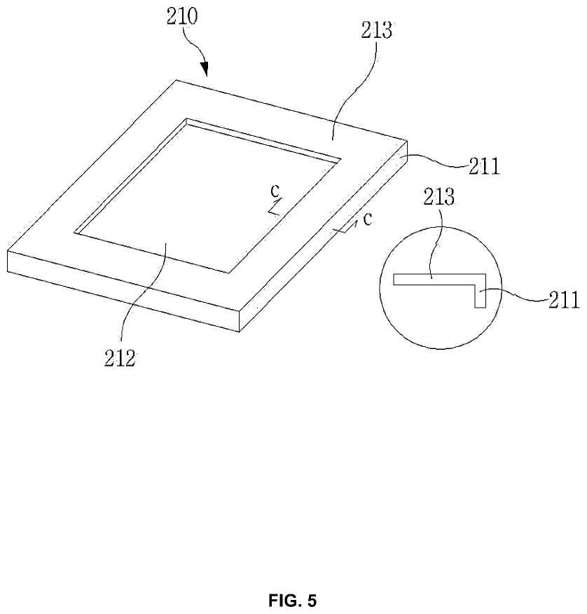

FIG. 5 is a view illustrating a modified example of the electromagnetic wave shielding apparatus.

An electromagnetic wave shielding apparatus 210 is provided with a vertical part 212 having a ring shape and a horizontal part 211 that extends inward from a top of the vertical part 212, both of which are integral.

An opening 212 may be defined at the center of the horizontal part 211, if necessary, the horizontal part 211 may be expanded so that the opening 212 is reduced in size or is not defined at all.

According to the structure, an area for dispersing and releasing heat may increase without raising the height of the body of the electromagnetic wave shielding apparatus 210.

When the opening 212 is defined relatively small or not defined, the body may have a shape similar to that of a metal shield case to efficiently shield the electromagnetic wave without the metal cover 20.

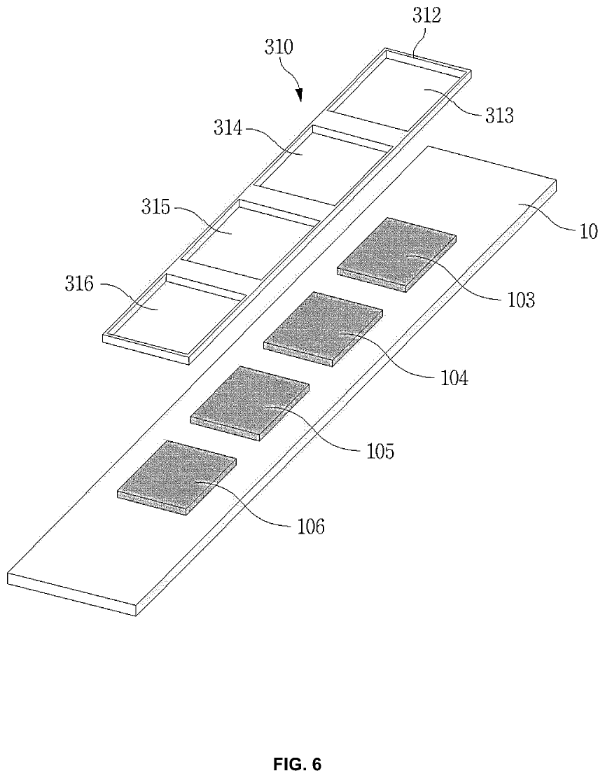

FIG. 6 is a view of an electromagnetic wave shielding apparatus according to another embodiment of the present invention.

In this embodiment, an electromagnetic wave shielding apparatus 310 is provided with a single metal body 310 in which a plurality of accommodation parts 313, 314, 315 and 316 are defined in a predetermined distance.

According to this structure, when a plurality of semiconductor chips 103, 104, 105 and 106 are mounted adjacent to each other on the circuit board 10, one electromagnetic wave shielding apparatus 310 may be used to allow each semiconductor chip 103, 104, 105 and 106 to be fitted into the accommodation parts 313, 314, 315 and 316 so that they are in contact with the side surfaces of the semiconductor chips.

This electromagnetic wave shielding apparatus 310 may be efficiently applied when a plurality of semiconductor chips 103, 104, 105, and 106, such as DRAMs, are provided with uniform size and are arranged at equal intervals on the circuit board 10.

The accommodation parts 313, 314, 315 and 316 may have a size which varies according to that of the semiconductor chips 103, 104, 105 and 106.

Although one of the semiconductor chips is accommodated into each of the accommodation parts 313, 314, 315 and 316 in an exemplary embodiment, the sizes and the arrangement of the accommodation parts of the body 312 may be adjusted so that a plurality of semiconductor chip is accommodated in one accommodation part.

According to the structure, each of the semiconductor chips mounted on the circuit board 10 may individually or entirely efficiently shield the electromagnetic wave and may also transfer and disperse the heat generated therefrom.

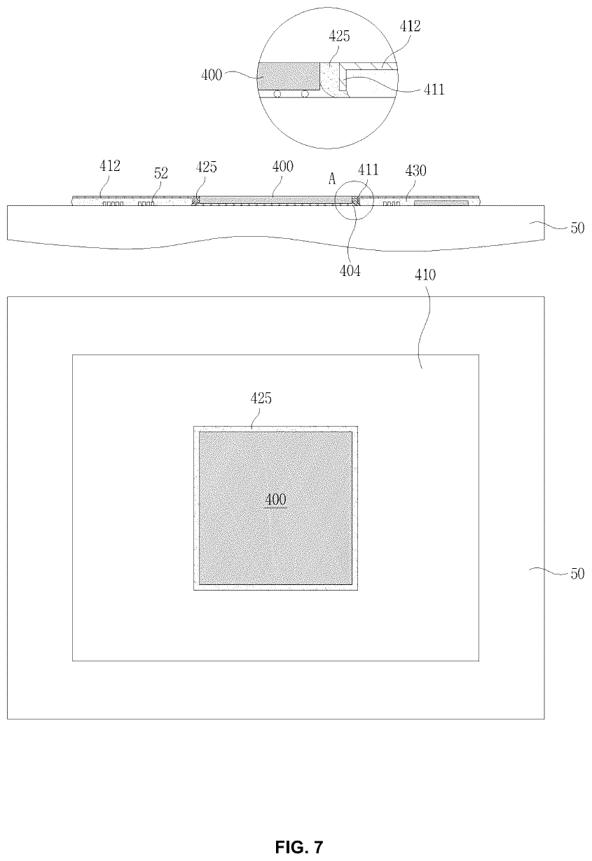

FIG. 7 is a view of an electromagnetic wave shielding apparatus according to another embodiment of the present invention.

In this embodiment, a semiconductor chip 400, for example, may be a semiconductor die processed from a semiconductor wafer, which applied to computer CPUs. An underfill 404 connected to a package substrate 50 is applied to a bottom surface of the semiconductor chip 400, and thus, the semiconductor chip 400 is mounted on the package substrate 50 using a flip-chip bonding method.

Like this, the semiconductor chip 400, which does not have an epoxy resin molding on the outside, has the disadvantage of being easily damaged by external forces, but it quickly transfers the heat generated from the semiconductor chip 400 to the outside.

An electromagnetic wave shielding apparatus 410 according to the embodiment includes a rectangular ring-shaped body 411 and a heat release part 412 horizontally expanded outward from the body 411.

An adhesive 425 is interposed between an inner surface of the body 411 and a side surface of the semiconductor chip 400 to adhere the body 411 and the semiconductor chip to each other, and the adhesive 425 may be interposed over the entire side surface of the semiconductor chip 400.

When the underfill 404 is provided, the adhesive 425 may cover the underfill 404.

Alternatively, a plurality of electronic components 52 and other semiconductor chips may be mounted on the package substrate 50. Here, those components may be disposed below the heat release part 412 of the electromagnetic wave shielding apparatus 410 and may be fixed to a bottom surface of the heat release part 412 using an electrically insulating, thermally conductive adhesive member 430.

According to this structure, since the body 411 is in contact with the semiconductor chip 400, on which an epoxy resin is not molded, with the adhesive 425 therebetween, the electromagnetic wave may be efficiently shield and quickly transfer the heat generated from the semiconductor chip 400 to the outside.

Particularly, since the heat release part 412 has a relatively large area, the heat generated from the semiconductor chip 400 may be quickly transferred or released to the outside.

In this embodiment, the electromagnetic wave shielding apparatus 410 has a rectangular ring-shaped body 411 corresponding to that of the semiconductor chip 400. Here, when the height of the semiconductor chip 400 is less than that of the body 411, body 411 may be manufactured as a metal plate in which an accommodation part that accommodates the semiconductor chip 400 therein.

Like this, an inner surface of the accommodation part of the metal plate, that is, a portion in a thickness direction of the accommodation part may be in contact with to be fixed to the side surface of the semiconductor chip 400 by the adhesive 425.

As described above, the electromagnetic wave shielding apparatus according to the present invention has the advantage of efficiently shielding the electromagnetic wave, while simultaneously transferring and dispersing the generated heat at the closest distance from the side surface of the semiconductor chip.

According to the apparatus for shielding the electromagnetic wave of the present invention, at least a portion of the inner surface of the ring-shaped body may be in contact with the side surface of the semiconductor chip, efficiently shielding the electromagnetic wave and transferring or dispersing the heat from the side surface of the semiconductor chip at the closest distance, while providing better thermal contact by the use of the thermal conductive adhesive.

Also, the thickness of the body constituting the apparatus for shielding the electromagnetic wave may be made thin, making it easier to apply to the circuit boards with limited space.

Also, when the apparatus for shielding the electromagnetic wave is made of elastic rubber material, the apparatus for shielding the electromagnetic wave may shield the electromagnetic wave of the semiconductor chip while being in contact with the side surface of the semiconductor chip.

Moreover, since the height of the apparatus for shielding the electromagnetic wave is the same as or slightly higher than that of the semiconductor chip mounted on the circuit board, the apparatus for shielding the electromagnetic wave may protect the semiconductor die or the semiconductor chip including the die from being pressed downward by the metal cover.

Furthermore, one the apparatus for shielding the electromagnetic wave may individually or entirely shield one or more semiconductor chips mounted on the circuit board to transfer or disperse the heat.

The above description has focused on the embodiments of the present invention, but various changes and modifications can be made by those skilled in the art. As long as these changes and modifications do not depart from the scope of the present invention, they are considered to fall within the scope of the invention. The scope of the present invention should be determined by the claims described below.

What is claimed is:

1. An apparatus for shielding an electromagnetic wave of a semiconductor package provided with a semiconductor chip mounted on a circuit board, the apparatus comprising:
a ring-shaped electrically conductive body,
wherein the body has heat resistance corresponding to a soldering temperature and comprises an accommodation part inside thereof, and
the semiconductor chip is accommodated in the accommodation part to allow the body to surround side surfaces of the semiconductor chip, thereby providing an electrically closed circuit, thereby shielding the electromagnetic wave, which leaking out from or is introduced into the side surfaces of the semiconductor chip,
wherein at least a portion of inner surfaces of the body is in contact with at least a portion of the side surfaces of the semiconductor chip.

2. The apparatus of claim 1, wherein the inner surfaces of the body are in elastic contact with each of the side surfaces of the semiconductor chip.

3. The apparatus of claim 1, wherein the body comprises:
a contact part that is in contact with and fixed along the side surfaces of the semiconductor chip; and
a shielding part that adheres to an outer surface of the contact part so as to be stacked.

4. The apparatus of claim 3, wherein the contact part and the shielding part have electrical resistance different from each other.

5. The apparatus of claim 1, wherein the body has a height that is the same as or higher than that of the semiconductor chip.

6. The apparatus of claim 1, wherein the body has a bottom surface that is in electric contact with a grounding pattern provided on the circuit board.

7. The apparatus of claim 1, wherein the at least a portion of the inner surfaces of the body is in direct contact with, or adheres to the at least one of the side surfaces of the semiconductor chip, using an adhesive therebetween.

8. The apparatus of claim 7, wherein the body and the adhesive have thermal conductivity.

9. The apparatus of claim 1, wherein the body comprises:
a vertical part; and
a horizontal part which extends inward from an upper end of the vertical part,
wherein the vertical part and the horizontal part are integrated with each other.

10. The apparatus of claim 1, further comprising a heat release part that is horizontally integrally expanded outward from the body.

11. The apparatus of claim 1, wherein the at least a portion of the inner surfaces of the body is spaced at a predetermined distance from the semiconductor chip, and
the bottom surface of the body adheres to the circuit board using an adhesive unit.

12. The apparatus of claim 1, wherein one or more semiconductor chips are accommodated in the accommodation part.

13. The apparatus of claim 12, wherein the at least a portion of the inner surfaces of the body is in direct contact with, or adheres to the at least one of the side surfaces of the semiconductor chip, using an adhesive therebetween.

14. The apparatus of claim 13, wherein the body and the adhesive have thermal conductivity.

15. The apparatus of claim 1, wherein the accommodation part, when the semiconductor chip is viewed from top to bottom in a vertical direction, allows the entire top surface of the semiconductor chip to be exposed to the outside.
